(19) United States
(12) Patent Application Publication
(10) Pub. No.: US 2022/0302046 A1
(43) Pub. Date: Sep. 22, 2022

(54) SEMICONDUCTOR DEVICE AND METHOD OF FABRICATING SEMICONDUCTOR DEVICE

(71) Applicant: LAPIS SEMICONDUCTOR CO., LTD., KANAGAWA (JP)

(72) Inventors: KIYOFUMI KONDO, KANAGAWA (JP); MAMORU ISHIKIRIYAMA, KANAGAWA (JP); TAKUMI INOUE, KANAGAWA (JP); KAZUTAKA KODAMA, KANAGAWA (JP); TOSHIFUMI KOBE, KANAGAWA (JP); YUZO YAMAMOTO, KANAGAWA (JP); TOSHIYUKI ORITA, KANAGAWA (JP); MAKOTO HIGASHIHIRA, KANAGAWA (JP)

(21) Appl. No.: 17/694,863

(22) Filed: Mar. 15, 2022

(30) Foreign Application Priority Data
Mar. 22, 2021 (JP) 2021-047721

(51) Int. Cl. H01L 23/00

(52) U.S. Cl. CPC H01L 23/562

(57) ABSTRACT

There is provided a semiconductor device including: a circuit region formed on one surface of a semiconductor substrate; a connection portion disposed at the one surface, the connection portion covering the circuit region, being electrically connected to the circuit region, and being used to connect with an exterior device; an annular wire formed at the one surface so as to surround the circuit region; a first protective film covering the annular wire, the first protective film being formed between the connection portion and a peripheral edge portion of the semiconductor substrate; and a second protective film formed at a predetermined partial region on the connection portion.

### CROSS-REFERENCE TO RELATED APPLICATION

This application is based on and claims priority under 35 USC 119 from Japanese Patent Application No. 2021-047721 filed on Mar. 22, 2021, the disclosure of which is incorporated by reference herein.

### BACKGROUND

### Technical Field

The present disclosure relates to a semiconductor device and a method of fabricating a semiconductor device.

### Related Art

One field of semiconductor devices is the field of vertical elements. Examples of vertical elements include FRDs (Fast Recovery Diodes), IGBTs (Insulated Gate Bipolar Transistors), and the like.

For example, Japanese Patent Application Laid-Open (JP-A) No. 2017-208490 discloses, as an example of an FRD, a fast recovery diode that includes an n-type semiconductor layer, and a p-type semiconductor layer that is layered on the n-type semiconductor layer. A pn junction is formed at the border of the n-type semiconductor layer and the p-type semiconductor layer. Crystal defects are formed such that the frequency of the appearance thereof gradually becomes smaller from the top surface of the p-type semiconductor layer toward the bottom surface of the n-type semiconductor layer. In JP-A No. 2017-208490, in fabricating the fast recovery diode, the reverse surface of the semiconductor wafer is, in a state of being joined to a supporting substrate, ground by back grinding or wet etching or the like, and the thickness of the entire semiconductor wafer, including the element structure portions at the obverse side, is made to be the desired thickness.

The structure disclosed in JP-A No. 2015-177116 for example is known as a semiconductor wafer or a chip (a semiconductor device) in an FRD fabrication process. The semiconductor device relating to JP-A No. 2015-177116 has: a semiconductor layer; a first electrode provided on the obverse of the semiconductor layer; plural second electrodes that are provided on the first electrode, and whose cross-sectional shape parallel to the obverse of the semiconductor layer is a rectangle having sides that are less than or equal to 50 micrometers; and a resin layer that is provided between the plural second electrodes and that has higher ductility than the second electrodes. A nickel electrode, which is a thick film and is obtained by carrying out nickel plating on the chip surface, is formed in order to increase the current density at the FRD and to provide suitability to packaging of double side cooling structures. In JP-A No. 2015-177116, warping of the semiconductor wafer or chip is suppressed by providing the nickel electrode on the first electrode such that the nickel electrode is divided among the plural second electrodes.

By the way, in vertical elements such as FRDs and IGBTs and the like, current flows from the circuit elements, which are formed at the obverse side of the semiconductor substrate, through semiconductor substrate and all the way to the reverse surface electrode that is formed at the reverse surface. If the thickness of the semiconductor substrate is thick, the resistance components are large, and problems such as, for example, the generation of heat, arise. Thus, in vertical elements such as FRDs and IGBTs and the like, generally, a semiconductor wafer is used whose thickness is made thin by grinding the reverse surface of the semiconductor wafer after the circuit elements have been formed, as can be seen in JP-A No. 2017-208490.

Surface burning is a problem in cases in which such grinding of the reverse surface of a semiconductor wafer is carried out. The problem of surface burning is described with reference to FIG. 6A, FIG. 6B, FIG. 7A, and FIG. 7B.

Reverse surface grinding is carried out while in the semiconductor wafer state, but FIG. 6A and FIG. 6B focus on a single semiconductor device that is on the surface of a semiconductor wafer, and illustrate the state of the semiconductor device. FIG. 6A shows the state of the semiconductor device before grinding of the reverse surface of a semiconductor wafer 23, and FIG. 6B shows the state of the semiconductor device after grinding of the reverse surface of the semiconductor wafer 23. Further, FIG. 7A and FIG. 7B illustrate the state of a grindstone that is used in grinding. FIG. 7A shows the state of the grindstone before grinding that corresponds to FIG. 6A, and FIG. 7B shows the state of the grindstone after grinding that corresponds to FIG. 6B.

As shown in FIG. 6A and FIG. 6B, unillustrated circuit elements are formed on the obverse of the semiconductor wafer 23, and protective films 15 are formed on these circuit elements. In a case of carrying out reverse surface grinding, as shown in FIG. 6A, first, a layered structure, in which a supporting member 22 of glass or the like is adhered to the obverse side of the semiconductor wafer 23 by an adhesive 21, is prepared. Then, a grindstone 30 is pressed against the reverse surface of the semiconductor wafer 23 at this layered structure, and grinding is carried out.

At this time, because the adhesive 21 is generally soft, there are cases in which, depending on the distance between the protective film 15 and the adjacent protective film 15, the adhesive 21 bends toward the supporting member 22 side as shown in FIG. 6B. Accompanying the bending of the supporting member 22, the semiconductor wafer 23 also bends toward the supporting member 22 side. When the semiconductor wafer 23 bends toward the supporting member 22 side, the pressure on the grindstone 30 decreases, and, at the grindstone 30 at which dressing could be carried out sufficiently before grinding as shown in FIG. 7A, the jaggedness decreases as shown in FIG. 7B. The reason for this is as follows. Generally, dressing is carried out by, as a grindstone grinds an object, the ground powder of the surface moving away and new ground powder appearing on the surface. However, by decreasing the pressure applied to the grindstone 30, dressing is no longer carried out efficiently.

If dressing of the grindstone 30 deteriorates (if the jaggedness decreases), the contact pressure between the grindstone 30 and the semiconductor wafer 23 decreases, and there becomes a state of so-called idling. Due to this idling, the ground surface of the semiconductor wafer 23 is scorched, and surface burning occurs. In the one semiconductor device that is on the surface of the semiconductor wafer 23, this scorching mainly arises due to the distribution of the protective films 15 at the semiconductor device. Because there are also cases in which the characteristics of the circuit regions formed on the obverse of the semiconductor wafer 23 change due to the surface burning, the occurrence of surface burning must be avoided as much as possible. Namely, conventionally, the suppressing of the problem of surface burning at a single semiconductor device has been required as a method of suppressing the problem of surface burning that arises due to the distribution of the protective films 15 that are formed at a single semiconductor device of the semiconductor wafer 23. Further, it is desirable that this method not involve changes such as the addition of steps in the process of fabricating the semiconductor device. In regard to this point, neither JP-A No. 2017-208490 nor JP-A No. 2015-177116 are documents addressing this problem of surface burning.

### SUMMARY

On the basis of the above-described circumstances, an object of the present disclosure is to, in a semiconductor device fabricated by fabrication processes including grinding the reverse surface of a semiconductor wafer by using a grindstone, and in a method of fabricating the semiconductor device, provide a semiconductor device and a method of fabricating the semiconductor device that can suppress the occurrence of surface burning at the obverse of the semiconductor wafer, and can do so without the further addition of fabrication steps.

In order to achieve the above-described object, a semiconductor device relating to the present disclosure includes: a circuit region formed on one surface of a semiconductor substrate; a connection portion disposed at the one surface, the connection portion covering the circuit region, being electrically connected to the circuit region, and being used to connect with an exterior device; an annular wire formed at the one surface so as to surround the circuit region; a first protective film covering the annular wire, the first protective film being formed between the connection portion and a peripheral edge portion of the semiconductor substrate; and a second protective film formed at a predetermined partial region on the connection portion.

In order to achieve the above-described object, a method of fabricating a semiconductor device relating to the present disclosure includes: forming a circuit region on one surface of a semiconductor substrate; forming a connection portion that is disposed at the one surface, the connection portion covering the circuit region, being electrically connected to the circuit region, and being used to connect with an exterior device; forming an annular wire at the one surface so as to surround the circuit region; forming simultaneously, of a same material, a first protective film, the first protective film covering the annular wire and being disposed between the connection portion and a peripheral edge portion of the semiconductor substrate, and a second protective film which is disposed at a predetermined partial region on the connection portion; attaching a supporting member to a surface at a circuit region side of the semiconductor substrate by using an adhesive member; and grinding a surface by using a grindstone, the surface being at a side opposite from the one surface of the semiconductor substrate.

In accordance with the present disclosure, the advantageous effect can be obtained of, in a semiconductor device fabricated by fabrication processes including grinding the reverse surface of a semiconductor wafer by using a grindstone, and in a method of fabricating the semiconductor device, being able to provide a semiconductor device and a method of fabricating the semiconductor device that can suppress the occurrence of surface burning at the obverse of the semiconductor wafer, and can do so without the further addition of fabrication steps.

### BRIEF DESCRIPTION OF THE DRAWINGS

Exemplary embodiments of the present disclosure will be described in detail based on the following figures, wherein:

FIG. 1A and FIG. 1B illustrate the structure of a semiconductor device relating to an exemplary embodiment, where FIG. 1A is a plan view, and FIG. 1B is a cross-sectional view;

FIG. 2A and FIG. 2B illustrate a semiconductor device relating to a comparative example, where FIG. 2A is a plan view, and FIG. 2B is a cross-sectional view;

FIG. 3A through FIG. 3C are partial cross-sectional views illustrating an example of a method of fabricating the semiconductor device relating to the exemplary embodiment;

FIG. 4A and FIG. 4B are partial cross-sectional views illustrating the example of a method of fabricating the semiconductor device relating to the exemplary embodiment;

FIG. 5A through FIG. 5C are drawings illustrating other forms of arrangements of second protective films at the semiconductor device relating to the exemplary embodiment;

FIG. 6A and FIG. 6B are partial drawings for explaining surface burning in reverse surface grinding of a semiconductor wafer; and

FIG. 7A and FIG. 7B are partial drawings for explaining surface burning in reverse surface grinding of a semiconductor wafer.

### DETAILED DESCRIPTION

Exemplary embodiments of the present disclosure are described in detail hereinafter with reference to the drawings. The exemplary embodiments that are described hereinafter describe, as examples, forms in which the semiconductor device relating to the present disclosure is applied to an FRD.

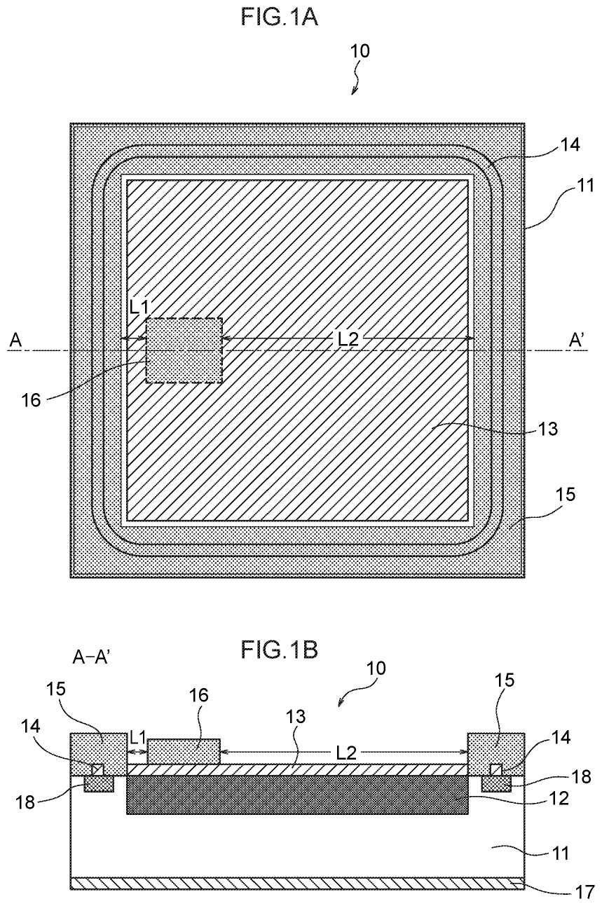

The structure of a semiconductor device 10 relating to the present exemplary embodiment is described with reference to FIG. 1A and FIG. 1B. FIG. 1A is a plan view in which the semiconductor device 10 is viewed from above, and FIG. 1B is a cross-sectional view that is cut along line A-A′ shown in FIG. 1A.

As shown in FIG. 1B, the semiconductor device 10 includes a semiconductor substrate 11, an impurity region 12, a pad 13, a ring-shaped wire (annular wire) 14, the first protective film 15, a second protective film 16, a reverse surface electrode 17 and a ring-shaped impurity region (annular impurity region) 18.

The semiconductor device 10 relating to the present exemplary embodiment is described by using FIG. 1A. The semiconductor substrate 11 is quadrangular as seen in a plan view, and, as an example, an N-type Si (silicon) is used as the material thereof. The pad 13 is disposed in the form of a quadrangle that is contained in the semiconductor substrate 11 as seen in a plan view, and is formed of a metal such as Al (aluminum) or the like for example. The ring-shaped wire 14 is disposed at the inner side of the semiconductor substrate 11 in an annular form that surrounds the pad 13 at the outer side of the pad 13 as seen in a plan view, and is formed of a metal such as Al (aluminum) or the like for example. The first protective film 15 is formed so as to cover the ring-shaped wire 14, and is formed by using a polyimide for example. The second protective film 16 is formed, for example, in a quadrangular shape at the inner side of the first protective film 15, and is formed by using the same material as the first protective film 15. Details of the second protective film 16 are described later.

As shown in FIG. 1B, the impurity region 12 is a region at which impurities are introduced into the obverse of the semiconductor substrate 11, and, for example, P-type impurities are introduced thereat. Further, at the semiconductor device 10, a PN junction is formed at the border of the N-type semiconductor substrate 11 and the P-type impurity region 12, and the semiconductor device 10 functions as a diode. When the positive electrode of a power source is connected to the pad 13, and the negative electrode of that power source is connected to the reverse surface electrode 17, diode current flows from the pad 13 toward the reverse surface electrode 17. Namely, through-current flows from the obverse to the reverse surface of the semiconductor substrate 11. Note that, in the present exemplary embodiment, as seen in a cross-sectional view such as in FIG. 1B, the region that includes the PN junction formed at the border of the N-type semiconductor substrate 11 and the P-type impurity region 12 is called the “circuit region” (“active region”).

As shown in FIG. 1B, the pad 13 is disposed at the upper portion of the impurity region 12. The pad 13 is a connecting portion for connection with the exterior device by, for example, a bonding wire or the like. In the present exemplary embodiment, the pad 13 is an anode terminal. Here, the exterior device may include a semiconductor device in which the semiconductor device 10 of the present embodiment is not provided, or a semiconductor device in which at least one of the semiconductor device 10 of the present embodiment is provided. Further, a new semiconductor device may be configured by the semiconductor device 10 of the present embodiment and the exterior device.

As shown in FIG. 1B, the ring-shaped wire 14 is disposed at the upper portion of the semiconductor substrate 11, at the outer side of the pad 13. The ring-shaped impurity region 18, which is a region into which P-type impurities are introduced, is formed directly beneath the ring-shaped wire 14. Although not illustrated in FIG. 1A, the ring-shaped impurity region 18 is formed in an annular shape in the same way as the ring-shaped wire 14. The ring-shaped impurity region 18 functions as a guard ring, and suppresses the occurrence of leakage current. Further, the ring-shaped wire 14 and the ring-shaped impurity region 18 have an electric field mitigation function. Namely, by using the ring-shaped wire 14 and the ring-shaped impurity region 18, the depletion layer that is formed at the border of the semiconductor substrate 11 and the impurity region 12 is extended to the peripheral edge portion that is the outer side of the semiconductor device 10, and electric field mitigation is carried out. Moreover, the ring-shaped wire 14 has the function of lowering the impurity concentration of the obverse of the semiconductor substrate 11, i.e., has a channel stopper function. Note that the present exemplary embodiment describes, as an example, a form in which the single ring-shaped wire 14 is used, but the present disclosure is not limited to this, and may be a form in which plural ring-shaped wires, such as double, triple or the like ring-shaped wires, are used in accordance with the pressure resistance and the like that are required of the semiconductor device 10.

As shown in FIG. 1B, the reverse surface electrode 17 is an electrode that is formed at the reverse surface of the semiconductor substrate 11, and is formed of a metal such as Al or the like for example. At the semiconductor device 10, the reverse surface electrode 17 is a cathode terminal.

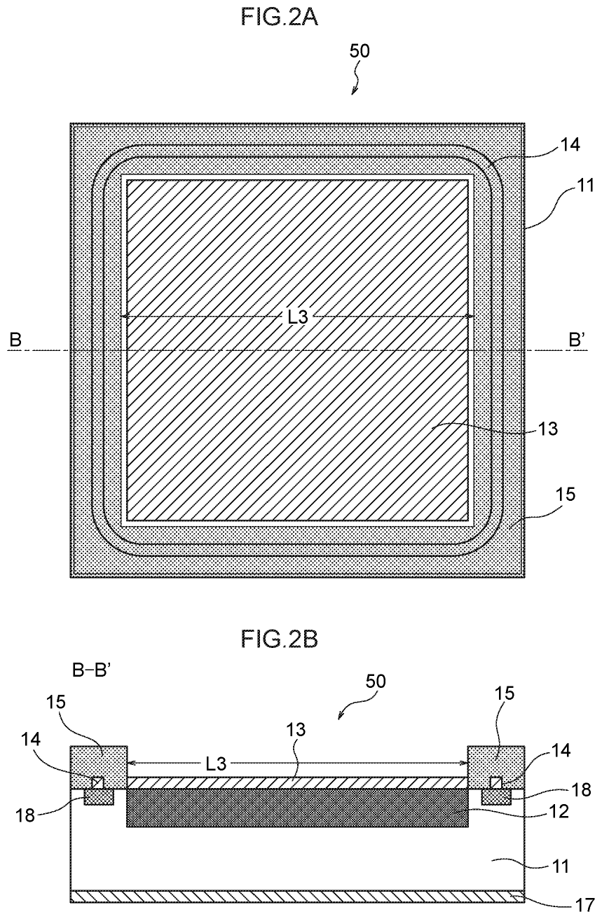

The functions of the second protective film 16 relating to the present exemplary embodiment are described next. However, before this, a semiconductor device 50 relating to a comparative example will be described with reference to FIG. 2A and FIG. 2B. FIG. 2A is a plan view in which the semiconductor device 50 is viewed from above, and FIG. 2B is a cross-sectional view that is cut along line B-B′ shown in FIG. 2A. The semiconductor device 50 is an FRD at which the second protective film 16 is eliminated from the semiconductor device 10 illustrated in FIG. 1A and FIG. 1B. Accordingly, similar structures are denoted by the same reference numerals, and detailed description thereof is omitted.

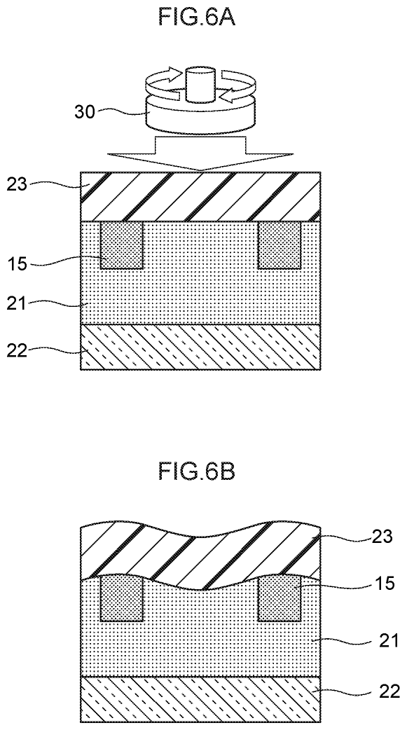

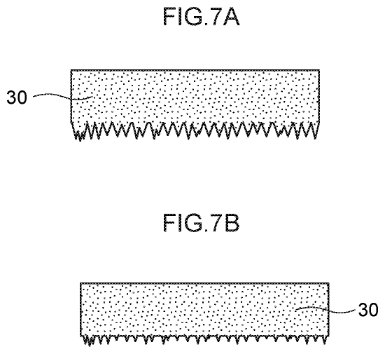

As shown in FIG. 2A and FIG. 2B, as compared with the semiconductor device 10, the semiconductor device 50 lacks the second protective film 16, and therefore, the entire pad 13 is exposed to the exterior. Namely, because a protective film does not exist between the left and right first protective films 15 in FIG. 2B, distance L3 between the protective films 15 of the semiconductor device 50 is long as compared with distances L1, L2 between the protective films 15 and the protective film 16 of the semiconductor device 10. Namely, because the semiconductor device 50 has a wider interval between the protective films than the semiconductor device 10, when reverse surface grinding is carried out as was described with reference to FIGS. 6A, 6B, 7A and 7B, it is easier for the adhesive 21 (an adhesive member) to deform at the pad 13 portion, and as a result, it is easy for the semiconductor wafer 23 to bend. Namely, in the semiconductor device 50 relating to the comparative example, it is easy for surface burning of the semiconductor wafer 23 to occur. Note that the distances L1, L2, L3 are examples.

Thus, the second protective film 16 is provided in the semiconductor device 10 relating to the present exemplary embodiment. As shown in FIG. 1B, due to the second protective film 16 being disposed between the two first protective films 15, the surface area that supports the adhesive 21 increases, and the pressure applied to the adhesive 21 increases, and therefore, bending of the adhesive 21 decreases. As a result, bending of the semiconductor wafer 23 also decreases, and surface burning of the semiconductor wafer 23 can be suppressed.

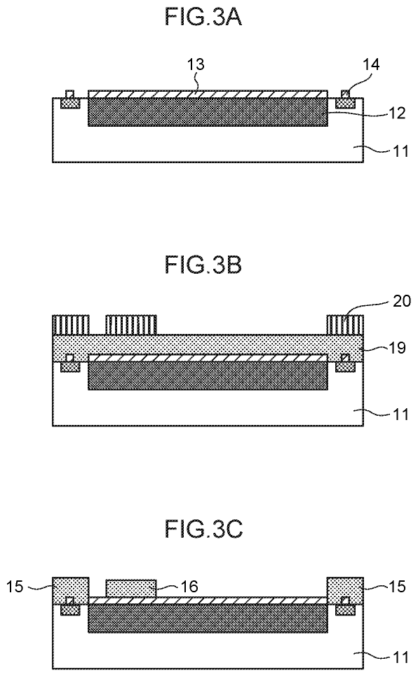

A method of fabricating the semiconductor device 10 relating to the present exemplary embodiment is described next with reference to FIG. 3A through FIG. 3C. Note that, although the semiconductor device 10 is fabricated in the state of being on a semiconductor wafer on whose surface are a plurality of the semiconductor devices 10, hereinafter, description is given while focusing on a single one of the semiconductor devices 10 thereamong.

First, the semiconductor substrate 11, on whose obverse circuit elements are formed, is prepared (FIG. 3A).

Next, a protective film 19 (e.g., a polyimide) is deposited on the entire surface. Then, a resist 20 is coated on the protective film 19, and a mask for forming the first protective film 15 and the second protective film 16 is created (exposed and developed, see FIG. 3B) by using photolithography and etching.

Next, the protective film 19 is etched, and the first protective film 15 and the second protective film 16 are formed (FIG. 3C). Thereafter, curing (hardening by heating) of the first protective film 15 and the second protective film 16 is carried out. Namely, the first protective film 15 and the second protective film 16 are simultaneously formed by the same material. Accordingly, the method of fabricating the semiconductor device 10 is the same as the method of fabricating the semiconductor device 50 relating to the comparative example, and there are no changes such as the addition of steps or the like.

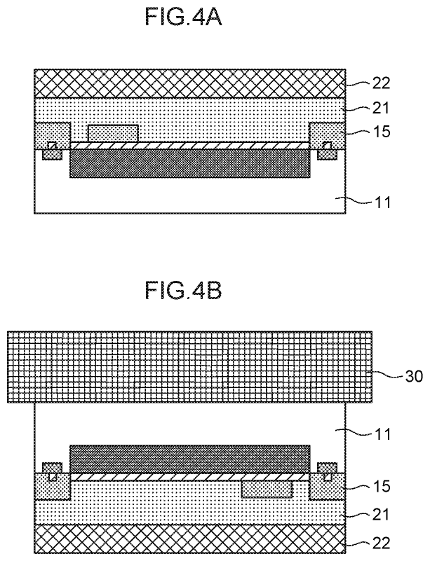

Next, the supporting member 22 (glass as an example) is attached by the adhesive 21 to the obverse (the circuit surface) side of the semiconductor substrate 11 (FIG. 4A).

Next, the semiconductor substrate 11 is turned upside-down, and the reverse surface of the semiconductor substrate 11 is ground by the grindstone 30, and the semiconductor substrate 11 is made to be a predetermined thickness (FIG. 4B).

Thereafter, the adhesive 21 and the supporting member 22 are removed, and the reverse surface electrode 17 is formed on the reverse surface of the semiconductor substrate 11 (this step is not illustrated). Thereafter, by dividing the semiconductor wafer into individual chips, the semiconductor device 10 relating to the present exemplary embodiment is fabricated.

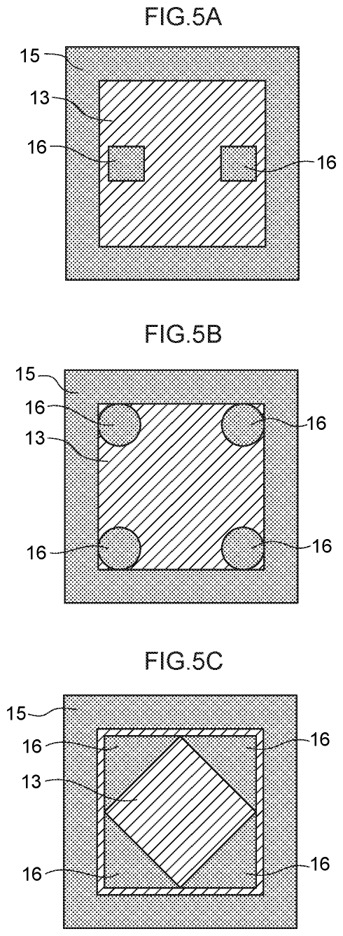

Other forms of methods of forming the second protective film 16 are described next with reference to FIG. 5A through FIG. 5C. FIG. 5A through FIG. 5C are drawings illustrating representative examples of the formation of the second protective film 16. FIG. 5A through FIG. 5C selectively illustrate only the pad 13, the first protective film 15 and the second protective films 16 among the structures illustrated in FIG. 1A. The region at which the second protective film 16 is disposed may be, specifically, at the region of the pad 13, any region other than regions where the protective film 16 cannot be provided, such as a region contacted by a probe for testing in the semiconductor wafer stage, a region to which a connecting member (e.g., a bonding wire) is connected after the dividing into the individual chips, and the like. Regions at which the protective film 16 cannot be provided differ per semiconductor device, in accordance with the contents of the testing in the semiconductor wafer stage, the method of connecting the pad 13 after division into the individual chips, and the like.

FIG. 5A through FIG. 5C are examples of arrangements of the second protective films 16 which are premised on the conditions that the region used for external connection is the center of the pad 13, and the region that is contacted by a probe for testing is at least one portion along the quadrangular peripheral edge of the pad 13, and protective films are not to be provided at these regions.

FIG. 5A is an example in which two of the second protective films 16 that are quadrangular are disposed along two opposing sides of the pad 13 that is quadrangular. In this way, there may be a plurality of the second protective films 16. FIG. 5B is an example in which the one second protective film 16 that is circular is disposed at each of the four corners of the pad 13 that is quadrangular, for a total of four of the second protective films 16. In this way, the shape of the second protective film 16 does not have to be quadrangular, and may be another shape, and, other than being circular, may be an arbitrary shape that can be disposed on the pad 13 such as oval, triangular, rhomboid, or the like. Further, the second protective films 16 may be disposed at the positions of the vertex angles, and not along the sides, of the pad 13 that is quadrangular. FIG. 5C is a form in which the second protective film 16, which is a shape having a rectangular opening, is disposed in a quadrangle that is apart from the first protective film 15 within the pad 13 that is quadrangular. By utilizing such a form, the surface area of the second protective films 16 can be increased while taking into consideration the above-described regions at which a protective film is not to be provided. Therefore, surface burning can be prevented more effectively.

In FIG. 5A through FIG. 5C, some gap is provided such that the first protective film 15 and the second protective films 16 do not contact one another. However, the second protective films 16 may be formed also at gaps between the first protective film 15 and the second protective films 16, such that the first protective film 15 and the second protective films 16 are made to contact one another. By utilizing such a form, the surface area of the second protective films 16 can be increased more, and therefore, surface burning can be prevented more effectively. Namely, it suffices for the second protective films 16 to be provided further toward the inner side than the first protective film 15, and the specific arrangement and shape thereof can be changed in accordance with the conditions.

The above exemplary embodiment describes, as an example, a form in which the second protective film 16 remains even after fabrication of the semiconductor device 10. However, the present disclosure is not limited to this, and the second protective film 16 may be removed in any step that is after the reverse surface grinding of the semiconductor substrate 11 and before the connecting of connecting members to the pad 13. Due thereto, constraints on the connecting of a bonding wire to the pad 13, or the like, are avoided.

Further, although the above exemplary embodiment describes, as an example, a vertical element as the semiconductor device relating to the present exemplary embodiment, the present disclosure is not limited to this, and may be applied to a semiconductor device of another form, such as a lateral element or the like.

What is claimed is:

1. A semiconductor device comprising:
a circuit region formed on one surface of a semiconductor substrate;
a connection portion disposed at the one surface, the connection portion covering the circuit region, being electrically connected to the circuit region, and being used to connect with an exterior device;
an annular wire formed at the one surface so as to surround the circuit region;
a first protective film covering the annular wire, the first protective film being formed between the connection portion and a peripheral edge portion of the semiconductor substrate;
and
a second protective film formed at a predetermined partial region on the connection portion.

2. The semiconductor device of claim 1, wherein the second protective film is formed so as to be apart from the first protective film.

3. The semiconductor device of claim 1, wherein the second protective film is disposed at a peripheral edge portion of the connection portion.

4. The semiconductor device of claim 1, wherein:
a shape of the connection portion as seen in plan view is quadrangular,
a plurality of second protective films are provided, and
each of the plurality of the second protective films is disposed along a side of the connection portion or at a corner portion of the connection portion.

5. The semiconductor device of claim 1, wherein the second protective film covers a peripheral edge portion of the connection portion and includes an opening portion at a region including a central portion of the connection portion.

6. The semiconductor device of claim 1, wherein the semiconductor device is a vertical element, a current at the vertical element flowing in a direction perpendicular to the semiconductor substrate.

7. The semiconductor device of claim 1, wherein the semiconductor device is an FRD device.

8. A method of fabricating a semiconductor device, the method comprising:
forming a circuit region on one surface of a semiconductor substrate;
forming a connection portion that is disposed at the one surface, the connection portion covering the circuit region, being electrically connected to the circuit region, and being used to connect with an exterior device;
forming an annular wire at the one surface so as to surround the circuit region;
forming simultaneously, of a same material, a first protective film, the first protective film covering the annular wire and being disposed between the connection portion and a peripheral edge portion of the semiconductor substrate, and a second protective film which is disposed at a predetermined partial region on the connection portion;
attaching a supporting member to a surface at a circuit region side of the semiconductor substrate by using an adhesive member; and
grinding a surface by using a grindstone, the surface being at a side opposite from the one surface of the semiconductor substrate.
